(19) United States
(12) Patent Application Publication
(10) Pub. No.: US 2008/0183404 A1
(43) Pub. Date: Jul. 31, 2008

(54) Monitoring heater condition to predict or detect failure of a heating element

(76) Inventors: Arsalan Alan Emami, Aliso Viejo, CA (US); Mitch Agamohamadi, Orange, CA (US); Saeed Sedehi, Orange, CA (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/008,597

(22) Filed: Jan. 11, 2008

Related U.S. Application Data
(60) Provisional application No. 60/880,171, filed on Jan. 13, 2007.

(51) Int. Cl. G01R 19/00; G08B 21/00; G06F 19/00

(52) U.S. Cl. 702/34; 340/640; 702/64

(57) ABSTRACT

An embodiment of the invention is a technique to generate warning of a failure of a heating element. An operational value of at least one of operating parameters of the heating element in a heater zone of a heating unit is monitored. A remaining life value of the at least one of the operating parameters is estimated. A warning is generated if the operational value exceeds a threshold value relative to the remaining life value.

### RELATED APPLICATION

This application claims the benefit of the provisional patent application titled “METHOD OF MONITORING HEATER CONDITION TO PREDICT OR DETECT FAILURE OF A RESISTANCE HEATING ELEMENT”, filed on Jan. 13, 2007, Ser. No. 60/880,171.

### BACKGROUND

1. Field of the Invention

Embodiments of the invention relate to heating equipment, and more specifically, to monitoring and predicting or detecting failure of heating elements.

2. Description of Related Art

Resistance wire electrical heating elements have been commonly used in many different applications. Typical uses are in electrically heated manufacturing process equipment such as furnaces used for semiconductor processing, or for sealing of ceramic packages for semiconductor devices, or furnaces for metal heat treating. Most of those applications use electrical heaters with multiple zones which are independently powered and controlled to achieve a desired distribution of heating of parts being processed. The resistance wire or resistive ceramic elements are subject to failures that are difficult to predict by visual inspection. When an element segment fails, no heat is produced in that area and the profile of heating may be shifted such that parts being processed will be unsuitable for the intended end use. Some or all parts in a process load may become scrap and if the failure is not detected, multiple loads may become unusable scrap.

In a typical diffusion furnace used in semiconductor manufacturing, a heater element used for 200 mm wafer processing is 20 inches in diameter and 40 inches in height. The heater typically includes three or five sections referred to as “Zones” which are independently powered and controlled by the main system controller. Semiconductor substrates, called wafers, are placed in a wafer carrier, also called a rack or boat and are placed for thermal processing within the central part of the heater element, called the “Flat Zone”. A thermal treatment as a step in the semiconductor device manufacturing process generally consists of heating to a lower set-point, stabilization of the temperature of the multiple parts and the carrier, followed by an increase in temperature and holding the parts for a selected time at the elevated set-point. At the elevated temperature various gases may be allowed to flow causing chemical or physical changes to the parts processed such as the growth of a protective oxide. That is followed by decrease of the furnace set-point, stabilization at the lower set-point and removal of the load of parts. That is generally followed by reloading the furnace and operation through a subsequent processing thermal cycle.

In typical resistance wire heating elements, the wire elongates when heated to the processing temperature. Upon cooling, most of the elongation is recovered but not all. After a sufficient number of cycles, and depending on the maximum temperature and ramping rates up and down, the wire in the element is permanently elongated and slightly reduced in cross-section compared to its initial condition. That elongation and decrease in cross-section results in an increase in the resistance and decrease in the power delivered to the zone of the heater element.

In current systems, the operating temperature range of the heater is 25-1700 degrees C. The resistance wire may be any commonly used material like Kanthal, Super-Kanthal, Molybdenum Disilicide, etc. When using heating wire made of Kanthal or Super-Kanthal based on metallic alloys of chromium, nickel and aluminum, the wire is protected from rapid oxidation by a surface layer of aluminum oxide (Al₂O₃) which forms on the surface of the heated wire operated in air. As the wire elongates with multiple cycles of service, cracks in the protective aluminum oxide layer are filled by creation of more protective oxide formed from aluminum diffusing from the wire core to the surface. However, as cycling is continued, the aluminum content of the wire is depleted until the oxide coating is no longer replenished sufficiently to protect the wire and the heating element enters an end-of-life or “wear-out” mode of failure. A break develops in the wire and current is no longer carried through the heating wire and there is a loss of heating in the affected zone of the heater.

Alternatively, during cycling and elongation, a local defect in the wire may result in local heating to or just above the melting point of the wire. Such a local defect may then produce failure within a few thermal cycles at a time well within the expected life of the heating element wire. If allowed to proceed to failure, a break in the wire results in failure to conduct current and loss of heating in that zone of the furnace.

In the past, failure has been detected by visual examination of the color of radiating hot elements or from temperature sensing devices such as thermocouples which may report one or more zone of the heater element failing to reach set-point temperature. At that point, a standard troubleshooting procedure is to cool the furnace and use an ohm meter to measure resistance of the individual segments (zones) of the heating element. A very high resistance value is the sign of a crack or open gap (failure) in the element. Current systems only detect either the “wear-out” or local defect modes of failure by a loss of heating after failure has occurred.

### SUMMARY OF THE INVENTION

An embodiment of the invention is a technique to generate warning of a failure of a heating element. An operational value of at least one of operating parameters of the heating element in a heater zone of a heating unit is monitored. A remaining life value of the at least one of the operating parameters is estimated. A warning is generated if the operational value exceeds a threshold value relative to the remaining life value.

### BRIEF DESCRIPTION OF THE DRAWINGS

Embodiments of the invention may best be understood by referring to the following description and accompanying drawings that are used to illustrate embodiments of the invention. In the drawings:

FIG. 1 is a diagram illustrating a system according to one embodiment of the invention.

FIG. 2 is a flowchart illustrating a process to generate warning of an impending failure of a heating element according to one embodiment of the invention.

FIG. 3 is a flowchart illustrating a process to establish initial characteristics according to one embodiment of the invention.

FIG. 4A is a flowchart illustrating a process to monitor according to one embodiment of the invention.

FIG. 4B is a flowchart illustrating a process to monitor according to one embodiment of the invention.

FIG. 5 is a flowchart illustrating a process to estimate remaining life value according to one embodiment of the invention.

FIG. 6 is a flowchart illustrating a process to generate a warning according to one embodiment of the invention.

FIG. 7 is a diagram illustrating a warning unit according to one embodiment of the invention.

FIG. 8 is a diagram illustrating a characteristic curve of the operational parameter according to one embodiment of the invention.

FIG. 9 is a diagram illustrating a computer system as the warning unit according to one embodiment of the invention.

### DETAILED DESCRIPTION OF THE INVENTION

An embodiment of the invention is a technique to generate warning of a failure of a heating element. An operational value of at least one of operating parameters of the heating element in a heater zone of a heating unit is monitored. A remaining life value of the at least one of the operating parameters is estimated. A warning is generated if the operational value exceeds a threshold value relative to the remaining life value.

In the following description, numerous specific details are set forth. However, it is understood that embodiments of the invention may be practiced without these specific details. In other instances, well-known circuits, structures, and techniques have not been shown in order not to obscure the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc

One embodiment of the invention provides a means for continuously monitoring the condition of the zones of the heating element and to provide a warning of impending failure while the heater is still performing within acceptable heating uniformity to prevent miss-processing of parts which may generate scrap that is unusable for the intended purpose.

The warning unit may use a general purpose microprocessor or special circuits for processing signals providing input information about the instantaneous current, voltage and temperature in the multiple zones of the heater element. The microprocessor is connected to memory modules which store instructional programs, data processing algorithms, generally in flash memory read only memory (ROM) as well as random access memory (RAM) for storage of data gathered from the heating element zones being monitored.

Each independently powered zone of the heating element is equipped with a current sensor which provides an analog signal, usually 0-5 volt direct current (DC) which is proportional to the current flow in that segment of the heating element. Thus, for a three zone heater there would be three (3) current sensors and for a five zone heater, five (5) current sensors. Each heater zone is monitored independently.

The alternating current (AC) voltage at each heater zone is monitored during set-up of the system and entered into a configuration file. Simultaneously with that zone measurement, the input line voltage (120 VAC) is measured and also entered into the configuration file. During operation of the early warning system, the voltage at the individual zones is computed using the current input line voltage and configuration file values. In addition, a thermocouple is used to provide a temperature signal (filtered and amplified to typically 0-5 volts dc) to the microprocessor.

When the system equipped with the early warning module is placed in operation, initial voltage-current characteristics of the heating element zones are measured and recorded during several initial cycles of operation. The initial data for each zone is filtered, averaged, and stored as indicative of the initial conditions of that zone of the heater element. During subsequent operating cycles, data for the power characteristics of each zone is collected and compared to the initial data file.

The failure curve for the resistance wire may be constructed using past data, experiments, or simulation. The failure is typically indicated by threshold value of the resistance of the wire. Other parameters that may be used to determined the failure includes voltage and temperature. There are typically two points on the failure curve at which a warning may be issued. The first point is at the 10% of the remaining life. The second point is at below 5% of the remaining life.

Changes in zone characteristics from the initial characteristics generally occur fairly linearly over the normal life span of an element and can be used to generate an estimate of remaining life of the element to a “wear-out” type failure. These characteristics include voltage, current, and temperature. The resistance value may be computed as R=V/I according to the Ohm's law. When the processor detects certain degrees of change from the initial values, the software may prompt the processor to generate a warning that the heater is predicted to be within 10% of end of normal life. That warning may be displayed as a visual signal, such as change in state of a light emitting diode (LED) display, a liquid crystal display (LCD) display, a personal computer (PC) display or a signal to the host system alerting, the operator or maintenance technician of a sign of an impending problem. With continued operation of the system, the processor may detect a shift in characteristics predictive of being within the last 5% of element life. Based on the software algorithm, the processor may then output a signal providing a more urgent level of warning such as a change in an LED display, activation of an audible alarm and an electrical signal to the host system.

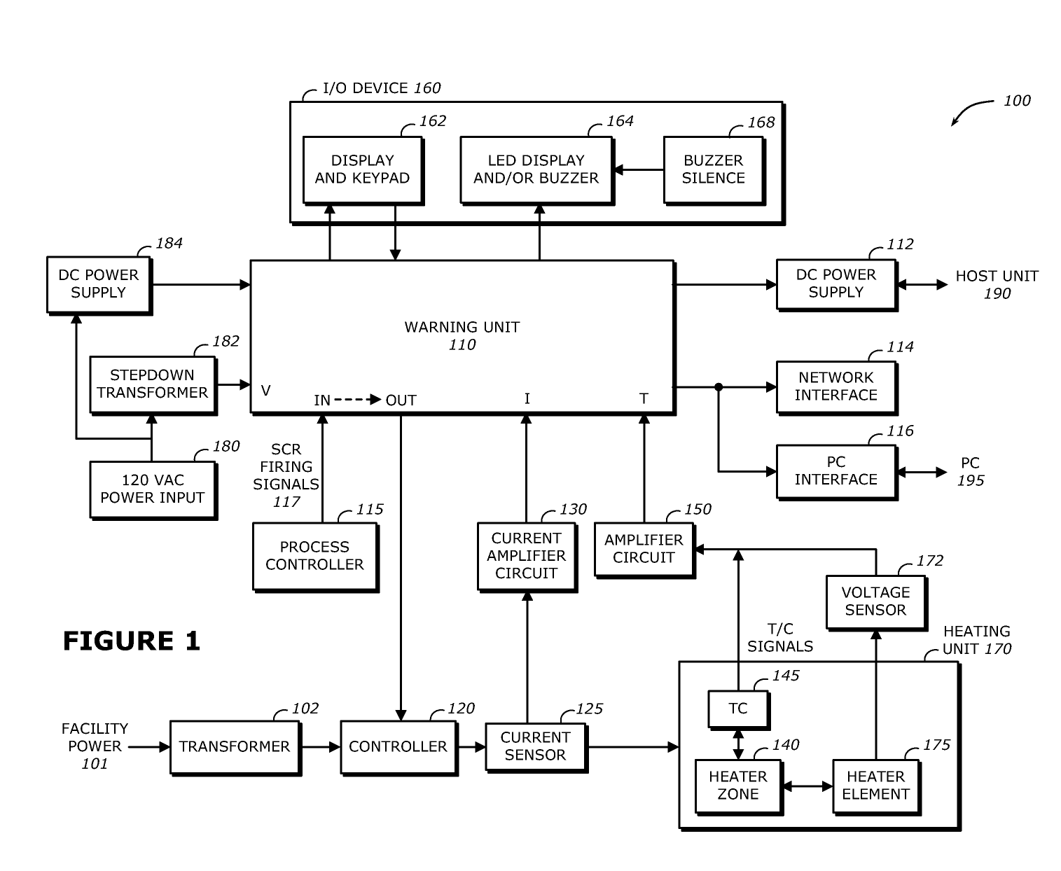

FIG. 1 is a diagram illustrating a system 100 according to one embodiment of the invention. The system 100 includes a warning unit 110, a controller 120, input/output device 160, and a heating unit 170. The heating unit 170 may include a heating element 175 used in a heating zone 140.

The warning unit 110 receives signals 117 used to control power to the heating element 175, and generates warning signals and/or automatically inhibits future operational cycles until the heating element 175 has been replaced and the monitoring system resets.

The facility power 101 provides power to the system. It is typically 208, 240, 380, 400, 420, 460 or 480 VAC, is fed through a zone transformer 102 which adjusts it to lower voltage and higher current appropriate for driving the heater. The output of the transformer is regulated by a silicon control rectifier (SCR) module in the controller 120 and fed to the heater zone 140. As current flows to the heater zone 140, it is sensed and measured by the current sensor 125 for that zone and a signal proportional to the current is sent through a current signal amplifier circuit 130 to the warning unit 110. The current amplifier circuit 130 may include an analog-to-digital converter (ADC) to convert the analog signal representing the sensed current to digital data.

The AC line input power 180, typically 120 VAC, is connected to a step-down transformer 182 and to a DC power supply 184 which generates the operating voltage for the warning unit 110.

Current flowing in the heater zone 140 increases the temperature and that rise is sensed by a zone thermocouple 145 which generates a low level voltage which is sent to an amplified circuit 150 which amplifies the thermocouple signal and sends it as an input to the warning unit 110. A voltage sensor 172 measures the voltage across the heating element 175 and sends the sensed voltage to the amplifier circuit 150. The amplifier circuit 150 may include one or more analog-to-digital converters (ADCs) to convert the analog signals representing the thermocouple value and the voltage value to digital data.

The main system process controller 115 controls the zone temperature by firing the SCR signals 117 that regulate the SCRs in the controller 120. The warning unit 110 may inhibit these signals 117, in case of an expecting element failure, from passing to the controller 120.

Firmware in the form of programmed instructions, initial configuration data, and operating data is stored within or connected to the warning unit 110. As a manufacturing cycle proceeds, the process controller 115 varies the zone set-point according to a planned and programmed sequence. As the steps of the cycle proceed, the warning unit 110 collects current data from the input signals from the line voltage step down transformer 182, the current sensor 125, the zone thermocouple 145, and the voltage sensor 172.

The warning unit 110 may have firmware/software that uses the collected data plus the initial configuration data to detect deviations in the electrical characteristics of the heater zone that may be an indication of an impending failure. If such failure is predicted based on the electrical characteristics, a signal is sent to a host system 190 via the host system interface 112 and the I/O device 160. The I/O device 160 may include a display and keypad 162, an LED display and/or buzzer 164, and a buzzer silencer 168.

A network interface 114 is provided to allow for networking of multiple early warning modules in a factory that can communicate with PCs 195 via a PC interface 116. The PC 195 may have software that has the capability of displaying a list of all the early warning modules on the network by their Internet Protocol (IP) address. By selecting an IP address, one can display and graph the current and historical data of a given heater zone 140. The configuration file may be modified by authorized personnel by entering the security pass code.

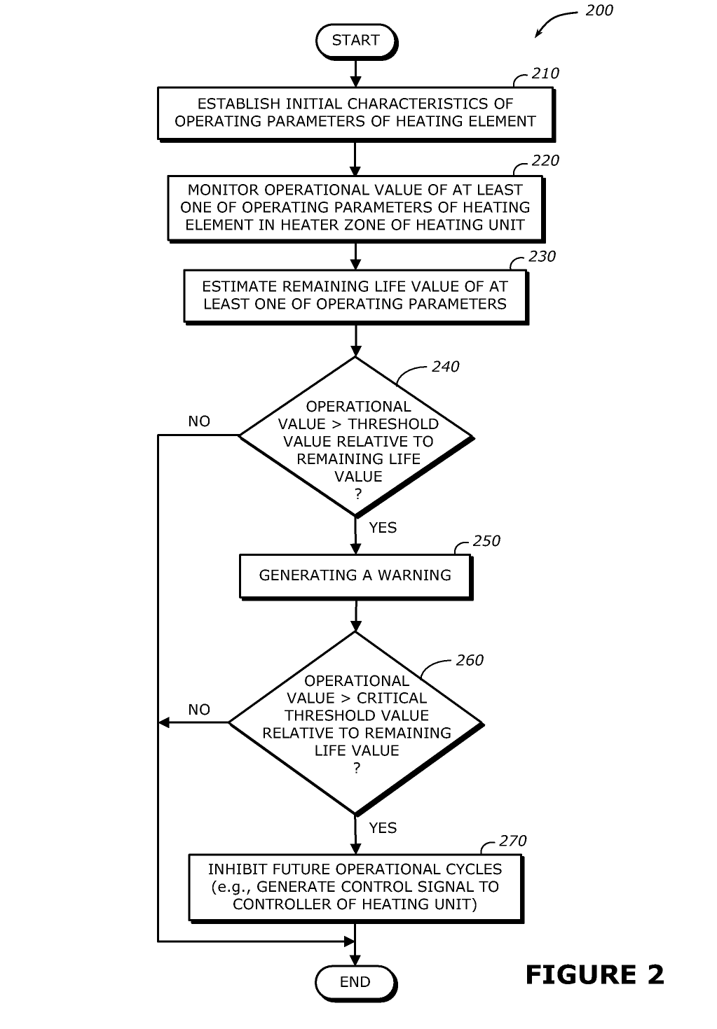

FIG. 2 is a flowchart illustrating a process 200 to generate warning of an impending failure of a heating element according to one embodiment of the invention.

Upon START, the process 200 establishes initial characteristics of the operating parameters of the heating element (Block 210). Next, the process 200 monitors an operational value of at least one of operating parameters of a heating element in a heater zone of a heating unit (Block 220). The monitoring may be used to measure an operational parameter (e.g., temperature) or to compute the resistance value of the heating element using the sensed voltage and current values. Then, the process 200 estimates a remaining life value of the at least one of the operating parameters (Block 230).

Next, the process 200 determines if the operational value exceeds a threshold value relative to the remaining life value (Block 240). If not, the process 200 is terminated. Otherwise, the process 200 generates a warning (Block 250). Then, the process 200 determines if the operational value exceeds a critical threshold value relative to the remaining life value (Block 260). The critical threshold value may be the same as the threshold value in Block 240. Typically, it is more critical. For example, the warning threshold value may be 10% and the critical threshold value may be 5%. If the operational value does not exceed the critical threshold value, the process 200 is terminated. Otherwise, the process 200 inhibits future operational cycles (Block 270). This may be performed by generating a control signal to a controller of the heating unit. The process 200 is then terminated.

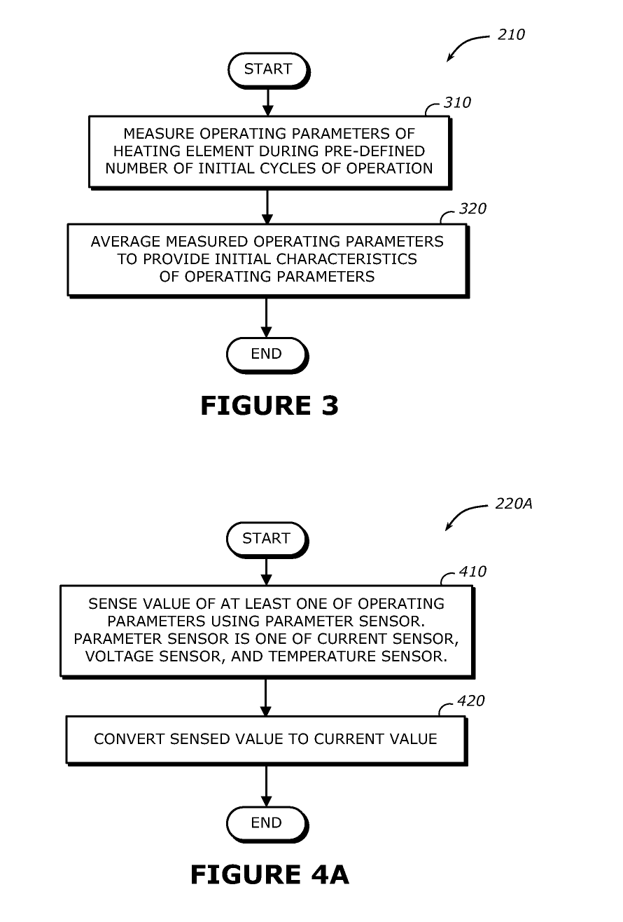

FIG. 3 is a flowchart illustrating the process 210 shown in FIG. 2 to establish initial characteristics according to one embodiment of the invention.

Upon START, the process 210 measures the operating parameters of the heating element during a pre-defined number of initial cycles of operation (Block 310). This may be performed by recording the sensed values of the operational parameters using a parameter sensor such as a voltage sensor, a current sensor, or a temperature sensor (e.g., a thermocouple element). The resistance of the heating element may be computed by dividing the sensed voltage value with the sensed current value according to the Ohm's law.

Next, the process 210 averages the measured operating parameters to provide the initial characteristics of the operating parameters (Block 320). The process 210 is then terminated.

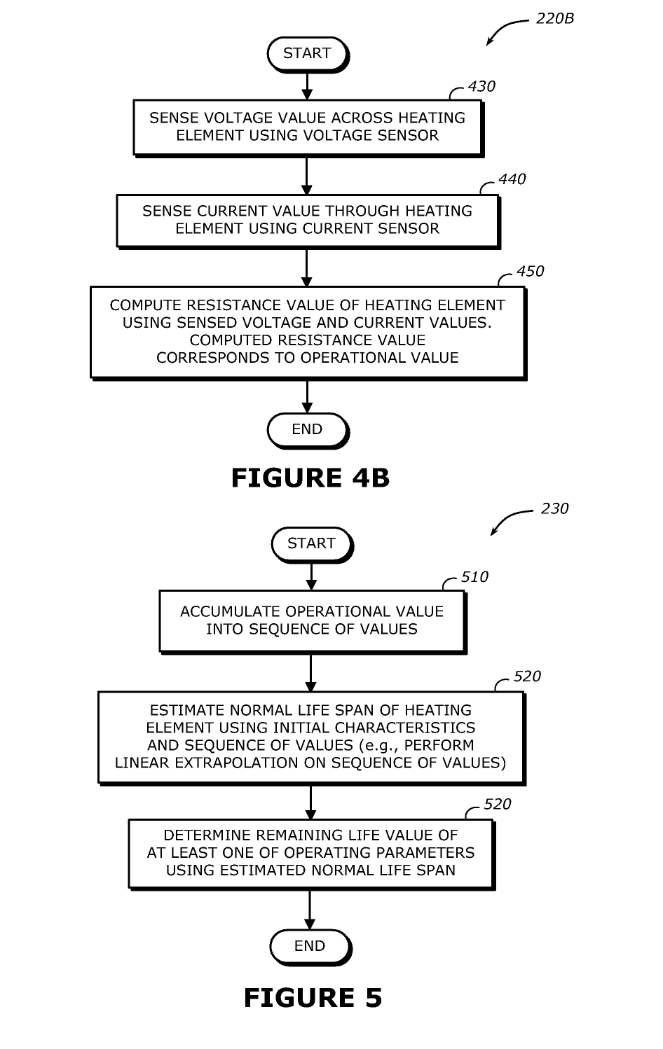

FIG. 4A is a flowchart illustrating a process 220A corresponding to the process 220 shown in FIG. 2 to monitor according to one embodiment of the invention.

Upon START, the process 220A senses a value of the at least one of the operating parameters using a parameter sensor (Block 410). The parameter sensor may be one of a current sensor, a voltage sensor, and a temperature sensor (e.g., a thermocouple element).

Next, the process 220A converts the sensed value to the operational value (Block 420). This may not be necessary if the sensed value is within the range of the operational value. The process 220A is then terminated.

FIG. 4B is a flowchart illustrating a process 220B corresponding to the process 220 shown in FIG. 2 to monitor according to one embodiment of the invention.

Upon START, the process 220B senses a voltage value across the heating element using a voltage sensor (Block 430). Next, the process 220B senses a current value through the heating element using a current sensor (Block 440). Then, the process 220B computes a resistance value of the heating element using the sensed voltage and current values (Block 450). This can be performed by dividing the sensed voltage value by the current value according to Ohm law. The computed resistance value corresponds to the operational value. The process 230B is then terminated.

FIG. 5 is a flowchart illustrating the process 230 shown in FIG. 2 to generate remaining life value according to one embodiment of the invention.

Upon START, the process 230 accumulates the operational value into a sequence of values (Block 510). This sequence of values includes all the operational values recorded after the initial period. Next, the process 230 estimates a normal life span of the heating element using the initial characteristics and the sequence of values (Block 520). This may be performed by performing an extrapolation on the sequence of values. The extrapolation may be a linear operation or non-linear extrapolation. The extrapolation may be a curve fitting procedure where the curve may represent a straight line for linear curve fitting, or a pre-determined curve (e.g., second or third order polynomial) for non-linear curve fitting. Then, the process 230 determines the remaining life value of the at least one of the operating parameters using the estimated normal life span (Block 530). This may be determined by computing the deviation of the extrapolated value on the normal life span with respect to the initial characteristics. The process 230 is then terminated.

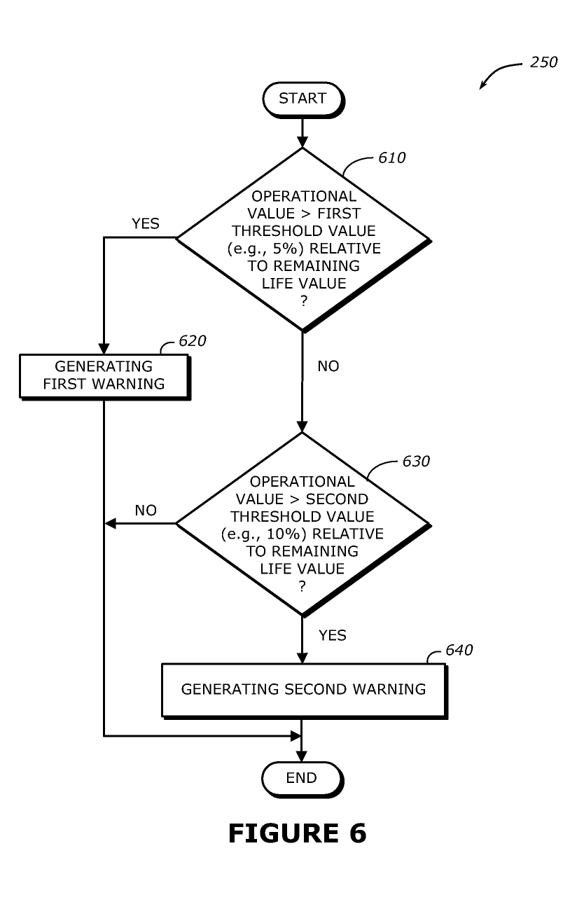

FIG. 6 is a flowchart illustrating the process 250 shown in FIG. 2 to generate a warning according to one embodiment of the invention.

Upon START, the process 250 determines if the operational value exceeds a first threshold value relative to the remaining life value (Block 610). The first threshold value may be a more critical threshold value. For example, it may be equal to 5% of the remaining life. If the operational value exceeds the first threshold value, the process 250 generates a first warning (Block 620). This may be performed by generating a warning light, sounding an audible alarm, or annunciating any warning message. The process 250 is then terminated.

If the operational value does not exceed the first threshold value, the process 250 determines if the operational value exceeds a second threshold value relative to the remaining life value (Block 630). The second threshold value may be a less critical threshold value than the first threshold value. For example, it may be equal to 10% of the remaining life. If the operational value does not exceed the second threshold value, the process 250 is terminated. Otherwise, the process 250 generates a second warning (Block 640). This may be performed by generating a warning light, sounding an audible alarm, or annunciating any warning message. The warning light, audible alarm or the warning message for the second warning may be of different nature (e.g., less critical) than those of the first warning.

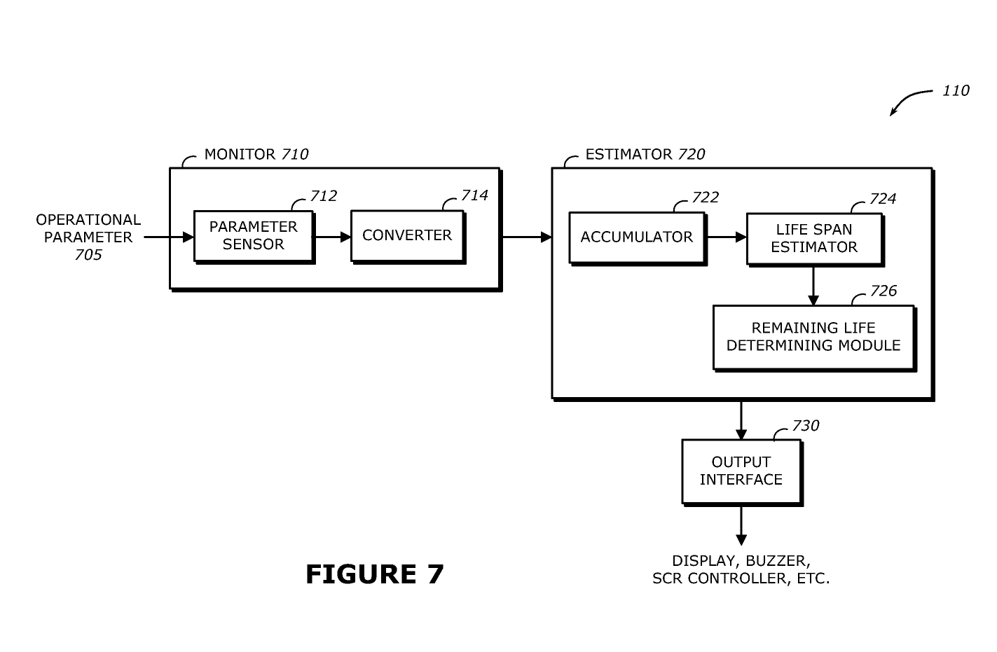

FIG. 7 is a diagram illustrating a warning unit 110 shown in FIG. 1 according to one embodiment of the invention. The warning unit 110 includes a monitor 710, an estimator 720, and an output interface 730. The warning unit 110 may include more or less than the above components.

The monitor 710 monitors an operational value of at least one of operating parameters of a heating element in a heater zone of a heating unit. It may include a parameter sensor 712 and a converter 714. The parameter sensor 712 senses a value of the at least one of the operating parameters. The parameter sensor may be one of a current sensor, a voltage sensor, and a temperature sensor. The converter 714 is coupled to the parameter sensor to convert the sensed value to the operational value.

The estimator 720 estimates a remaining life value of the at least one of the operating parameters. It may include an accumulator 722, a life span estimator 724, and a remaining life determining module 726. The accumulator 722 accumulates the operational value into a sequence of values. The life span estimator 724 estimates a normal life span of the heating element using initial characteristics and the sequence of values. The remaining life determining module 726 determines the remaining life value of the at least one of the operating parameters using the estimated normal life span.

The output interface 730 is coupled to the estimator to generate the warning if the operational value exceeds a threshold value relative to the remaining life value. The output interface 730 may be interfaced to the display, the buzzer, and/or the controller that controls the heating unit, etc.

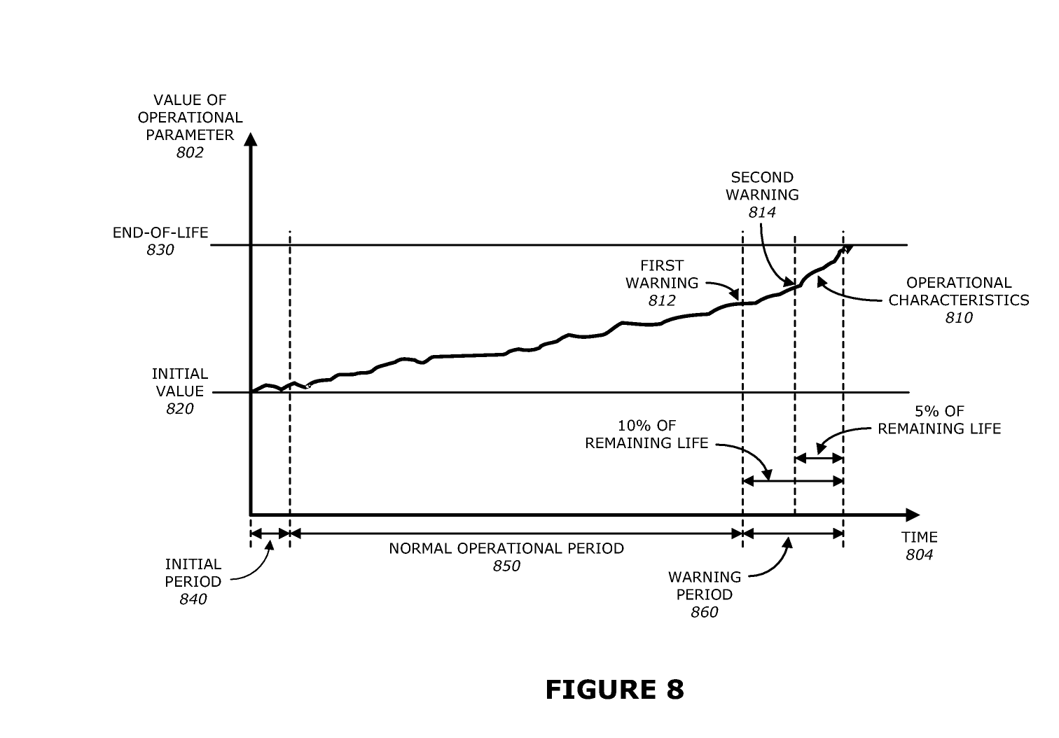

FIG. 8 is a diagram illustrating a characteristic curve of the operational parameter according to one embodiment of the invention. The operational characteristic 810 is the characteristic curve representing the value of the operational parameter during the life span of the heating element. The operational parameter may be voltage, current, temperature, or the resistance value of the heating element. For illustrative purposes, the operational characteristic 810 represents the resistance value of the heating element.

The vertical axis represents the value 802 of the operational parameter. The horizontal axis represents the time 804. The characteristic 810 has a range of values from the initial value 820 to the end-of-life value 830.

The life span of the heating element may be divided into three periods: an initial period 840, a normal operational period 850, and a warning period 860. The initial period 840 is the period that the heating element is first put into operation. During this initial period 840, the initial characteristics of the operational parameter are established as shown in FIG. 2. During the normal operational period 850, the operational values are monitored and accumulated to predict or estimate the remaining life as described above. During the warning period 860, there is an impending failure of the heating element. The first warning 812 is first generated at the time where the operational value exceeds the first threshold (e.g., 10%) relative to the remaining life value. The second warning 814 is generated at the time where the operational value exceeds the second threshold (e.g., 5%) relative to the remaining life value.

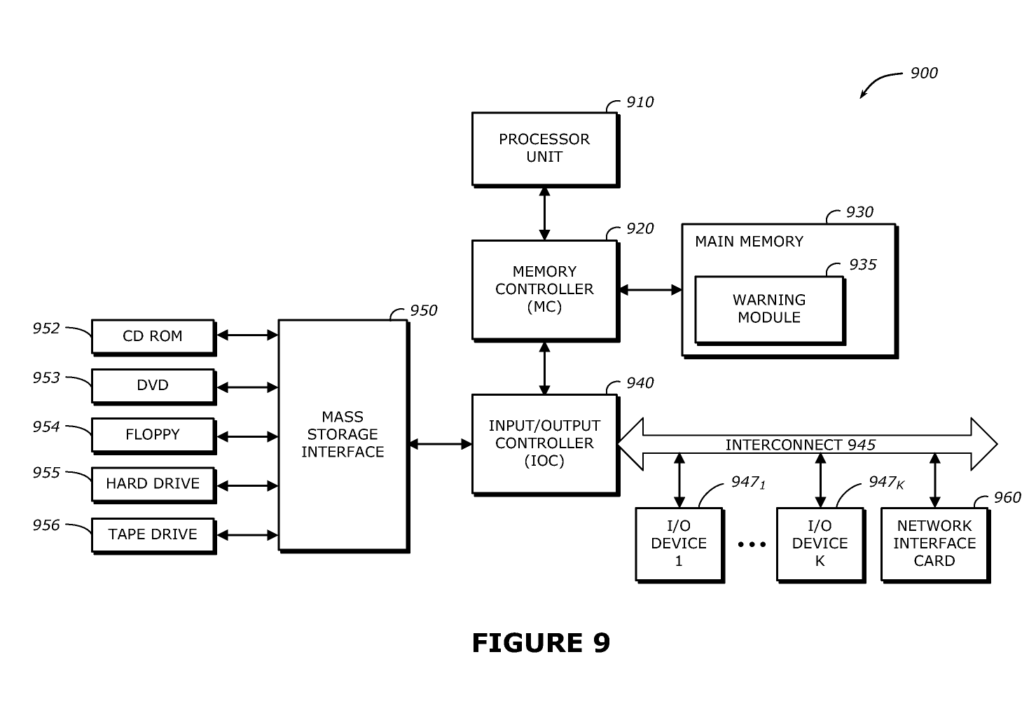

FIG. 9 is a diagram illustrating a processing unit 900 to implement the warning unit 110, the host unit 190, or the PC 195 shown in FIG. 1 according to one embodiment of the invention. The processing unit 900 includes a processor 910, a memory controller (MC) 920, a main memory 930, an input/output controller (IOC) 940, an interconnect 945, a mass storage interface 950, input/output (I/O) devices 947₁ to 947_{K}, and a network interface card (NIC) 960. The processing unit 900 may include more or less of the above components.

The processor 910 represents a central processing unit of any type of architecture, such as processors using hyper threading, security, network, digital media technologies, single-core processors, multi-core processors, embedded processors, mobile processors, micro-controllers, digital signal processors, superscalar computers, vector processors, single instruction multiple data (SIMD) computers, complex instruction set computers (CISC), reduced instruction set computers (RISC), very long instruction word (VLIW), or hybrid architecture.

The MC 920 provides control and configuration of memory and input/output devices such as the main memory 930 and the IOC 940. The MC 920 may be integrated into a chipset that integrates multiple functionalities such as graphics, media, isolated execution mode, host-to-peripheral bus interface, memory control, power management, etc. The MC 920 or the memory controller functionality in the MC 920 may be integrated in the processor unit 910. In some embodiments, the memory controller, either internal or external to the processor unit 910, may work for all cores or processors in the processor unit 910. In other embodiments, it may include different portions that may work separately for different cores or processors in the processor unit 910.

The main memory 930 stores system code and data. The main memory 930 is typically implemented with dynamic random access memory (DRAM), static random access memory (SRAM), or any other types of memories including those that do not need to be refreshed. The main memory 930 may include multiple channels of memory devices such as DRAMs. The DRAMs may include Double Data Rate (DDR2) devices with a bandwidth of 8.5 Gigabyte per second (GB/s). In one embodiment, the memory 930 may include a warning module 935. The warning module 935 may perform all or some of the functions described above.

The IOC 940 has a number of functionalities that are designed to support I/O functions. The IOC 940 may also be integrated into a chipset together or separate from the MC 920 to perform I/O functions. The IOC 940 may include a number of interface and I/O functions such as peripheral component interconnect (PCI) bus interface, processor interface, interrupt controller, direct memory access (DMA) controller, power management logic, timer, system management bus (SMBus), universal serial bus (USB) interface, mass storage interface, low pin count (LPC) interface, wireless interconnect, direct media interface (DMI), etc.

The interconnect 945 provides interface to peripheral devices. The interconnect 945 may be point-to-point or connected to multiple devices. For clarity, not all interconnects are shown. It is contemplated that the interconnect 945 may include any interconnect or bus such as Peripheral Component Interconnect (PCI), PCI Express, Universal Serial Bus (USB), Small Computer System Interface (SCSI), serial SCSI, and Direct Media Interface (DMI), etc.

The mass storage interface 950 interfaces to mass storage devices to store archive information such as code, programs, files, data, and applications. The mass storage interface 950 may include SCSI, serial SCSI, Advanced Technology Attachment (ATA) (parallel and/or serial), Integrated Drive Electronics (IDE), enhanced IDE, ATA Packet Interface (ATAPI), etc. The mass storage device may include high-capacity high speed storage arrays, such as Redundant Array of Inexpensive Disks (RAIDs), Network Attached Storage (NAS), digital tapes, optical storage, etc.

The mass storage device may include compact disk (CD) read-only memory (ROM) 952, digital video/versatile disc (DVD) 953, floppy drive 954, hard drive 955, tape drive 956, and any other magnetic or optic storage devices. The mass storage device provides a mechanism to read machine-accessible media.

The I/O devices 947₁ to 947_{K} may include any I/O devices to perform I/O functions. Examples of I/O devices 947₁ to 947_{K} include controller for input devices (e.g., keyboard, mouse, trackball, pointing device), media card (e.g., audio, video, graphic), and any other peripheral controllers.

The NIC 960 provides network connectivity to the processing unit 230. The NIC 960 may generate interrupts as part of the processing of communication transactions. In one embodiment, the NIC 960 is compatible with both 32-bit and 64-bit peripheral component interconnect (PCI) bus standards. It is typically compliant with PCI local bus revision 2.2, PCI-X local bus revision 1.0, or PCI-Express standards. There may be more than one NIC 960 in the processing system. Typically, the NIC 960 supports standard Ethernet minimum and maximum frame sizes (64 to 6518 bytes), frame format, and Institute of Electronics and Electrical Engineers (IEEE) 802.2 Local Link Control (LLC) specifications. It may also support full-duplex Gigabit Ethernet interface, frame-based flow control, and other standards defining the physical layer and data link layer of wired Ethernet. It may support copper Gigabit Ethernet defined by IEEE 802.3ab or fiber-optic Gigabit Ethernet defined by IEEE 802.3z.

The NIC 960 may also be a host bus adapter (HBA) such as a Small Computer System Interface (SCSI) host adapter or a Fiber Channel (FC) host adapter. The SCSI host adapter may contain hardware and firmware on board to execute SCSI transactions or an adapter Basic Input/Output System (BIOS) to boot from a SCSI device or configure the SCSI host adapter. The FC host adapter may be used to interface to a Fiber Channel bus. It may operate at high speed (e.g., 2 Gbps) with auto speed negotiation with 1 Gbps Fiber Channel Storage Area Network (SANsz). It may be supported by appropriate firmware or software to provide discovery, reporting, and management of local and remote HBAs with both in-band FC or out-of-band Internet Protocol (IP) support. It may have frame level multiplexing and out of order frame reassembly, on-board context cache for fabric support, and end-to-end data protection with hardware parity and cyclic redundancy code (CRC) support.

Elements of one embodiment of the invention may be implemented by hardware, firmware, software or any combination thereof. The term hardware generally refers to an element having a physical structure such as electronic, electromagnetic, optical, electro-optical, mechanical, electromechanical parts, etc. A hardware implementation may include circuits, devices, processors, applications specific integrated circuits (ASICs), programmable logic devices (PLDs), field programmable gate arrays (FPGAs), or any electronic devices. The term software generally refers to a logical structure, a method, a procedure, a program, a routine, a process, an algorithm, a formula, a function, an expression, etc. The term firmware generally refers to a logical structure, a method, a procedure, a program, a routine, a process, an algorithm, a formula, a function, an expression, etc., that is implemented or embodied in a hardware structure (e.g., flash memory, ROM, EPROM). Examples of firmware may include microcode, writable control store, micro-programmed structure. When implemented in software or firmware, the elements of an embodiment of the present invention are essentially the code segments to perform the necessary tasks. The software/firmware may include the actual code to carry out the operations described in one embodiment of the invention, or code that emulates or simulates the operations. The program or code segments can be stored in a processor or machine accessible medium or transmitted by a computer data signal embodied in a carrier wave, or a signal modulated by a carrier, over a transmission medium. The “processor readable or accessible medium” or “machine readable or accessible medium” may include any medium that can store, transmit, or transfer information. Examples of the processor readable or machine accessible medium include a storage medium, an electronic circuit, a semiconductor memory device, a read only memory (ROM), a flash memory, an erasable programmable ROM (EPROM), a floppy diskette, a compact disk (CD) ROM, an optical disk, a hard disk, a fiber optic medium, a radio frequency (RF) link, etc. The computer data signal may include any signal that can propagate over a transmission medium such as electronic network channels, optical fibers, air, electromagnetic, RF links, etc. The code segments may be downloaded via computer networks such as the Internet, Intranet, etc. The machine accessible medium may be embodied in an article of manufacture. The machine accessible medium may include information or data that, when accessed by a machine, cause the machine to perform the operations or actions described above. The machine accessible medium may also include program code embedded therein. The program code may include machine readable code to perform the operations or actions described above. The term “information” or “data” here refers to any type of information that is encoded for machine-readable purposes. Therefore, it may include program, code, data, file, etc.

All or part of an embodiment of the invention may be implemented by various means depending on applications according to particular features, functions. These means may include hardware, software, or firmware, or any combination thereof. A hardware, software, or firmware element may have several modules coupled to one another. A hardware module is coupled to another module by mechanical, electrical, optical, electromagnetic or any physical connections. A software module is coupled to another module by a function, procedure, method, subprogram, or subroutine call, a jump, a link, a parameter, variable, and argument passing, a function return, etc. A software module is coupled to another module to receive variables, parameters, arguments, pointers, etc. and/or to generate or pass results, updated variables, pointers, etc. A firmware module is coupled to another module by any combination of hardware and software coupling methods above. A hardware, software, or firmware module may be coupled to any one of another hardware, software, or firmware module. A module may also be a software driver or interface to interact with the operating system running on the platform. A module may also be a hardware driver to configure, set up, initialize, send and receive data to and from a hardware device. An apparatus may include any combination of hardware, software, and firmware modules.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising
monitoring an operational value of at least one of operating parameters of a heating element in a heater zone of a heating unit;
estimating a remaining life value of the at least one of the operating parameters; and
generating a warning if the operational value exceeds a threshold value relative to the remaining life value.

2. The method of claim 1 wherein the operating parameters include voltage, current, and temperature.

3. The method of claim 1 further comprising:
establishing initial characteristics of the operating parameters of the heating element.

4. The method of claim 3 wherein establishing the initial characteristics comprises:
measuring the operating parameters of the heating element during a pre-defined number of initial cycles of operation; and
averaging the measured operating parameters to provide the initial characteristics of the operating parameters.

5. The method of claim 1 wherein monitoring comprises:
sensing a value of the at least one of the operating parameters using a parameter sensor, the parameter sensor being one of a current sensor, a voltage sensor, and a temperature sensor; and
converting the sensed value to the operational value.

6. The method of claim 3 wherein estimating the remaining life value comprises:
accumulating the operational value into a sequence of values;
estimating a normal life span of the heating element using the initial characteristics and the sequence of values; and
determining the remaining life value of the at least one of the operating parameters using the estimated normal life span.

7. The method of claim 6 wherein estimating the normal life span comprises:
performing a linear extrapolation on the sequence of values.

8. The method of claim 5 wherein monitoring comprises:
sensing a voltage value across the heating element using a voltage sensor;
sensing a current value through the heating element using a current sensor; and
computing a resistance value of the heating element using the sensed voltage and current values, the computed resistance value corresponding to the operational value.

9. The method of claim 5 wherein generating the warning comprises:
generating a first warning if the operational value exceeds a first threshold value relative to the remaining life value; and
generating a second warning if the operational value exceeds a second threshold value relative to the remaining life value.

10. The method of claim 9 wherein the first and second threshold values are approximately 5% and 10% of the remaining life value.

11. The method of claim 1 further comprising:
inhibiting future operational cycles if the operational value exceeds a critical threshold value relative to the remaining life value.

12. The method of claim 11 wherein inhibiting comprising:
generating a control signal to a controller of the heating unit.

13. An article of manufacture comprising:
a machine-accessible medium including data that, when accessed by a machine, causes the machine to perform operations comprising:
monitoring an operational value of at least one of operating parameters of a heating element in a heater zone of a heating unit;
estimating a remaining life value of the at least one of the operating parameters; and
generating a warning if the operational value exceeds a threshold value relative to the remaining life value.

14. The article of manufacture wherein the data further comprises data that, when accessed by a machine, causes the machine to perform operations comprising:
establishing initial characteristics of the operating parameters of the heating element.

15. The article of manufacture of claim 14 wherein the data causing the machine to perform establishing the initial characteristics comprises data that, when accessed by the machine, causing the machine to perform operations comprising:
measuring the operating parameters of the heating element during a pre-defined number of initial cycles of operation; and
averaging the measured operating parameters to provide the initial characteristics of the operating parameters.

16. The article of manufacture of claim 13 wherein the data causing the machine to perform monitoring comprises data that, when accessed by the machine, causing the machine to perform operations comprising:
sensing a value of the at least one of the operating parameters using a parameter sensor, the parameter sensor being one of a current sensor, a voltage sensor, and a temperature sensor; and
converting the sensed value to the operational value.

17. The article of manufacture of claim 14 wherein the data causing the machine to perform estimating the remaining life value comprises data that, when accessed by the machine, causing the machine to perform operations comprising:
accumulating the operational value into a sequence of values;
estimating a normal life span of the heating element using the initial characteristics and the sequence of values; and
determining the remaining life value of the at least one of the operating parameters using the estimated normal life span.

18. An apparatus comprising:
a monitor to monitor an operational value of at least one of operating parameters of a heating element in a heater zone of a heating unit,
an estimator to estimate a remaining life value of the at least one of the operating parameters, and
an output interface coupled to the estimator to generate the warning if the operational value exceeds a threshold value relative to the remaining life value.

19. The apparatus of claim 18 wherein the monitor comprises:
a parameter sensor to sense a value of the at least one of the operating parameters, the parameter sensor being one of a current sensor, a voltage sensor, and a temperature sensor; and
a converter coupled to the parameter sensor to convert the sensed value to the operational value.

20. The apparatus of claim 18 wherein the estimator comprises:
an accumulator to accumulate the operational value into a sequence of values;
a life span estimator to estimate a normal life span of the heating element using initial characteristics and the sequence of values; and
a remaining life determining module to determine the remaining life value of the at least one of the operating parameters using the estimated normal life span.
